(19) United States
(12) Patent Application Publication
(10) Pub. No.: US 2025/0246553 A1
(43) Pub. Date: Jul. 31, 2025

(54) INTERCONNECT SUBSTRATE AND METHOD OF MAKING INTERCONNECT SUBSTRATE

(71) Applicant: SHINKO ELECTRIC INDUSTRIES CO., LTD., Nagano (JP)

(72) Inventor: Akihiro TAKEUCHI, Nagano (JP)

(21) Appl. No.: 19/027,748

(22) Filed: Jan. 17, 2025

(30) Foreign Application Priority Data
Jan. 30, 2024 (JP) 2024-012047

(51) Int. Cl. H01L 23/538; H01L 23/66

(52) U.S. Cl. CPC H01L 23/5383; H01L 23/5386; H01L 23/66; H01L 2223/6616; H01L 2223/6677

(57) ABSTRACT

An interconnect substrate includes a first insulating layer having a first surface, a pad disposed on the first surface, a second insulating layer disposed on the first surface and covering the pad, the second insulating layer having a second surface facing the first surface and a third surface opposite the second surface, and a first interconnect layer disposed on the third surface, and a third insulating layer disposed on the third surface and covering the first: interconnect layer, wherein a recess penetrates the first insulating layer and the second insulating layer and has an end surface in the third insulating layer, and wherein an opening is formed in the first insulating layer, and the pad is exposed through the opening.

### CROSS-REFERENCE TO RELATED APPLICATIONS

The present application is based on and claims priority to Japanese Patent Application No. 2024-012047 filed on Jan. 30, 2024, with the Japanese Patent Office, the entire contents of which are incorporated herein by reference.

### FIELD

The disclosures herein relate to interconnect substrates and methods of making an interconnect substrate.

### BACKGROUND

Interconnect substrates having a cavity for mounting electronic components are known in the art.

In such interconnect substrates, forming a deep cavity stably is difficult.

There may be a need for an interconnect substrate that allows the stable formation of a deep cavity, and for a method of making such an interconnect substrate.

### RELATED ART DOCUMENTS

### Patent Documents

[Patent Document 1] Japanese Laid-Open Patent Publication No. 2010-141204
[Patent Document 2] Japanese Laid-Open Patent Publication No. 2023-093291

### SUMMARY

According to an aspect of the embodiment, an interconnect substrate includes a first insulating layer having a first surface, a pad disposed on the first surface, a second insulating layer disposed on the first surface and covering the pad, the second insulating layer having a second surface facing the first surface and a third surface opposite the second surface, and a first interconnect layer disposed on the third surface, and a third insulating layer disposed on the third surface and covering the first interconnect layer, wherein a recess penetrates the first insulating layer and the second insulating layer and has an end surface in the third insulating layer, and wherein an opening is formed in the first insulating layer, and the pad is exposed through the opening.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating an example of the structure of an interconnect substrate according to an embodiment;

FIGS. 2A through 2C are cross-sectional views illustrating an example of a method of making the interconnect substrate according to the embodiment;

FIGS. 3A through 3C are cross-sectional views illustrating the example of the method of making the interconnect substrate according to the embodiment;

FIGS. 4A through 4C are a cross-sectional views illustrating the example of the method of making the interconnect substrate according to the embodiment;

FIGS. 5A and 5B are cross-sectional views illustrating the example of the method of making the interconnect substrate according to the embodiment;

FIGS. 6A and 6B are cross-sectional views illustrating the example of the method of making the interconnect substrate according to the embodiment;

FIGS. 7A through 7C are cross-sectional views illustrating the example of the method of making the interconnect substrate according to the embodiment;

FIGS. 8A and 8B are cross-sectional views illustrating examples of usages of the interconnect substrate according to the embodiment; and

FIGS. 9A and 9B are cross-sectional views illustrating examples of interconnect substrates according to variations of the embodiment and the usages of the interconnect substrates.

### DESCRIPTION OF EMBODIMENTS

In the following, embodiments of the present disclosure will be described with reference to the accompanying drawings. In the instant specification and the drawings, components having substantially the same functional configuration may be referred to by the same reference numeral, and a duplicate description thereof may be omitted. In this disclosure, for the sake of convenience, the side of an object oriented in the same direction as the side of an interconnect substrate where a cavity is provided is referred to as an A side or lower side, and the opposite side is referred to as a B side or upper side. The surface of an object oriented in the same direction as the surface of the interconnect substrate on the side with the cavity is referred to as an A-side surface or lower surface, and the surface on the opposite side is referred to as a B-side surface or upper surface. However, the interconnect substrate may be placed upside down when used, or may be arranged at any angle. The plan view refers to the view of an object as seen from the direction normal to the A-side surface of the interconnect substrate, and the plane shape refers to the shape of an object as seen from the direction normal to the A-side surface of the interconnect substrate.

[Structure of Interconnect Substrate according to Embodiment]

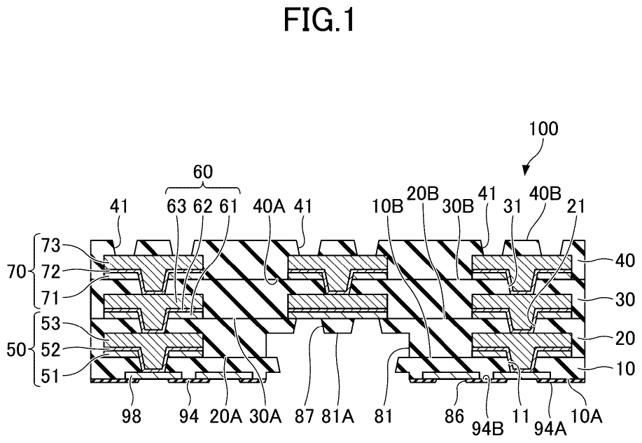

First, the structure of an interconnect substrate according to the embodiment will be described. FIG. 1 is a cross-sectional view illustrating an example of the structure of the interconnect substrate according to the embodiment.

As illustrated in FIG. 1, an interconnect substrate 100 according to the embodiment includes insulating layers 94, 10, 20, 30, and 40, pads 98, and interconnect layers 50, 60, and 70.

The insulating layer 94 has an A-side surface 94A and a B-side surface 94B opposite to the A-side surface. The A-side surface 94A is a lower surface and the B-side surface 94B is an upper surface. The insulating layer 94 is, for example, a primer layer or a prepreg. The prepreg may or may not contain a glass cloth. The insulating layer 94 may be made of an insulating resin such as epoxy resin or polyimide resin. The insulating layer 94 is an example of a first insulating layer, and the surface 94B is an example of a first surface.

The pads 98 are disposed on the B-side surface 94B of the insulating layer 94. The pads 98 each include, for example, a metal foil, such as copper (Cu) or copper alloy. The thickness of the pads 98 is about 1.5 μm to 5 μm. As an example, the pads 98 are used for connection with one or more electronic components. Alternatively, they may be used as external connection terminals.

The insulating layer 10 is disposed on the B-side surface 94B of the insulating layer 94 and covers the pads 98. The insulating layer 10 has an A-side surface 10A and a B-side surface 10B opposite to the surface 10A. The surface 10A faces the surface 94B. The insulating layer 10 is, for example, a prepreg. The prepreg may or may not contain a glass cloth. The insulating layer 10 may be made of an insulating resin such as an epoxy resin or a polyimide resin. Via holes 11 are formed in the insulating layer 10. The via holes 11 penetrate the insulating layer 10. The via holes 11 overlap the respective pads 98 in plan view and reach the respective pads 98. The via holes 11 may each be an inverted truncated conical recess. That is, each of the via holes 11 is structured such that the opening diameter at the upper end may be larger than the opening diameter at the lower end. The insulating layer 10 is an example of a second insulating layer, and the surface 10A is an example of a second surface, and the surface 10B is an example of a third surface.

The interconnect layer 50 is disposed on the B-side surface 10B of the insulating layer 10. The interconnect layer 50 includes, for example, a copper or copper alloy foil 51, a copper or copper alloy seed layer 52, and a copper or copper alloy plating layer 53. At least a part of the interconnect layer 50 is electrically connected to at least some of the pads 98 through the via holes 11. The foil 51 is disposed on the surface 10B. An opening connected to a via hole 11 is formed in the foil 51, and the seed layer 52 is disposed on the upper surface of a pad 98, the inner wall surface of the via hole 11, the inner wall surface of the opening formed in the foil 51, and the upper surface of the foil 51. The plating layer 53 is disposed on the seed layer 52. The interconnect layer 50 is an example of a first interconnect layer.

The insulating layer 20 is disposed on the B-side surface 10B of the insulating layer 10 and covers the interconnect layer 50. The insulating layer 20 has an A-side surface 20A and a B-side surface 20B opposite to the surface 20A. The surface 20A faces the surface 10B. The material of the insulating layer 20 is the same as that of the insulating layer 10, for example. Via holes 21 are formed in the insulating layer 20. The via holes 21 penetrate the insulating layer 20. The via holes 21 overlap the interconnect layer 50 in plan view and reach the interconnect layer 50. The via holes 21 may each be an inverted truncated conical recess. That is, each of the via holes 21 is structured such that the opening diameter at the upper end may be larger than the opening diameter at the lower end. The insulating layer 20 is an example of a third insulating layer. The surface 20A is an example of a fourth surface, and the surface 20B is an example of a fifth surface.

The interconnect layer 60 is disposed on the B-side surface 20B of the insulating layer 20. The interconnect layer 60 includes, for example, a copper or a copper alloy foil 61, a copper or a copper alloy seed layer 62, and a copper or a copper alloy plating layer 63. At least a part of the interconnect layer 60 is electrically connected to the interconnect layer 50 through the via holes 21. The foil 61 is disposed on the surface 20B. An opening connected to a via hole 21 is formed in the foil 61, and the seed layer 62 is disposed on the upper surface of the interconnect layer 50, the inner wall surface of the via hole 21, the inner wall surface of the opening formed in the foil 61, and the upper surface of the foil 61. The plating layer 63 is disposed on the seed layer 62. The interconnect layer 60 is an example of a second interconnect layer.

The insulating layer 30 is disposed on the B-side surface 20B of the insulating layer 20 and covers the interconnect layer 60. The insulating layer 30 has an A-side surface 30A and a B-side surface 30B opposite to the surface 30A. The surface 30A faces the surface 20B. The material of the insulating layer 30 is the same as that of the insulating layer 10, for example. Via holes 31 are formed in the insulating layer 30. The via holes 31 penetrate the insulating layer 30. The via holes 31 overlap the interconnect layer 60 in plan view and reach the interconnect layer 60. The via holes 31 may each be an inverted truncated conical recess. That is, each of the via holes 31 is structured such that the opening diameter at the upper end may be larger than the opening diameter at the lower end.

The interconnect layer 70 is disposed on the B-side surface 30B of the insulating layer 30. The interconnect layer 70 includes, for example, a copper or copper alloy foil 71, a copper or copper alloy seed layer 72, and a copper or copper alloy plating layer 73. At least a part of the interconnect layer 70 is electrically connected to the interconnect layer 60 through the via holes 31. The foil 71 is disposed on the surface 30B. An opening connected to a via hole 31 is formed in the foil 71, and the seed layer 72 is disposed on the upper surface of the interconnect layer 60, the inner wall surface of the via hole 31, the inner wall surface of the opening formed in the foil 71, and the upper surface of the foil 71. The plating layer 73 is disposed on the seed layer 72. The interconnect layer 70 is an example of a third interconnect layer.

The insulating layer 40 is disposed on the B-side surface 30B of the insulating layer 30 and covers the interconnect layer 70. The insulating layer 40 has an A-side surface 40A and a B-side surface 40B opposite to the surface 40A. The surface faces 40A the surface 30B. The material of the insulating layer 40 is the same as that of the insulating layer 10, for example. Openings 41 are formed in the insulating layer 40. The openings 41 penetrate the insulating layer 40. The openings 41 overlap the interconnect layer 70 in plan view and reach the interconnect layer 70. The openings 41 may each be an inverted truncated conical recess. That is, each of the openings 41 is structured such that the aperture diameter at the upper end may be larger than the aperture diameter at the lower end. As an example, the interconnect layer 70 exposed in the openings 41 is used for connection with one or more electronic components. Alternatively, it is used as external connection terminals.

In the manner described above, a laminate structure of the insulating layers 30 and 40 is disposed on the surface 20B of the insulating layer 20 and covers the interconnect layer 60. The interconnect layer 70 is provided between the adjacent insulating layers 30 and 40. The insulating layers 30 and 40 are an example of fourth insulating layers, and an interconnect layer 70 is an example of a third interconnect layer.

A cavity 81 is formed in the insulating layers 94, 10, and 20. The cavity 81 penetrates the insulating layers 94 and 10, and has an end surface 81A in the insulating layer 20. Openings 86 are formed in the insulating layer 94. The openings 86 penetrate the insulating layer 94. The openings 86 overlap the respective pads 98 in plan view and reach the respective pads 98. The pads 98 are exposed in the openings 86. Openings 87 reaching the interconnect layer 60 are formed in the insulating layer 20 from the end surface 81A of the cavity 81. The openings 86 and 87 may each be a truncated conical recess. That is, each of the openings 86 and 87 is structured such that the opening diameter at the lower end may be larger than the opening diameter at the upper end.

### [Method of Making Interconnect Substrate]

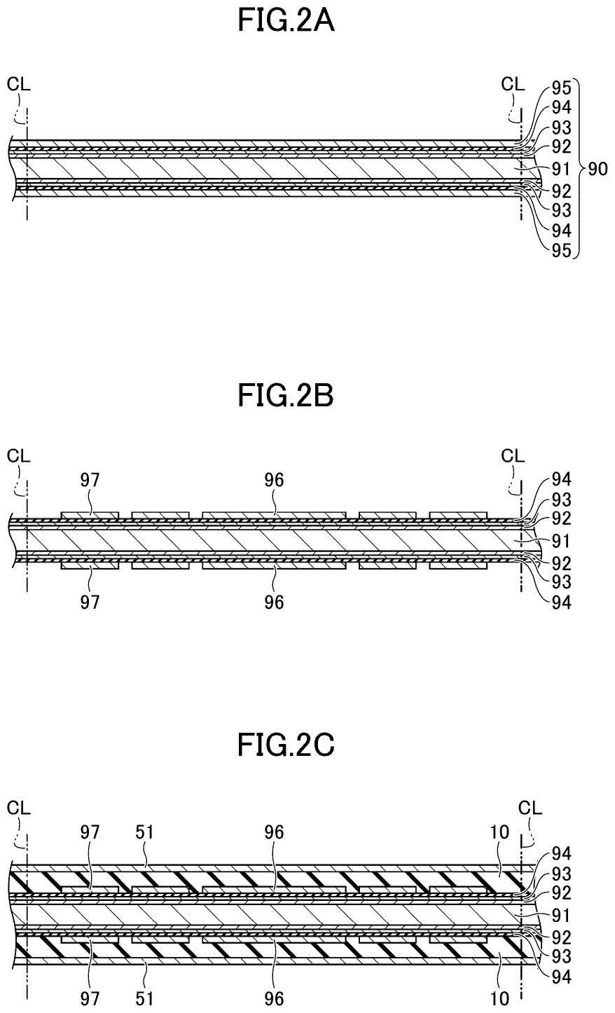

In the following, a method of making the interconnect substrate according to the embodiment will be described. FIGS. 2A through 2C to FIGS. 7A through 7C are cross-sectional views illustrating an example of a method of making the interconnect substrate according to the embodiment.

First, as illustrated in FIG. 2A, a support substrate 90 is prepared. The support substrate 90 includes, for example, a prepreg substrate 91, carrier foils 92, foils 93, insulating layers 94, and foils 95. On each of the A side and the B side of the substrate 91, a carrier foil 92 is placed on the surface of the substrate 91, a foil 93 is placed on the surface of the carrier foil 92, an insulating layer 94 is placed on the surface of the foil 93, and a foil 95 is placed on the surface of the insulating layer 94. The substrate 91 is prepared by impregnating, for example, a woven fabric or a nonwoven fabric such as glass fiber or aramid fiber with a thermosetting epoxy resin or polyimide resin in advance. The foils 93 and 95 are, for example, metal foils such as copper or copper alloy. The foil 93 may be thinner than the foil 95. The carrier foil 92 and the foil 93 are laminated together via a release layer (not shown) made of an inorganic material or an organic material.

The support substrate 90 is a large-sized support substrate which from plurality a of interconnect substrates 100 are generated. That is, the support substrate 90 has a plurality of areas in each of which the structure corresponding to the interconnect substrate 100 is formed. After the respective structures to become the interconnect substrates 100 are simultaneously made, the structures are singulated into individual interconnect substrates 100 by cutting along the cutting lines CL. It should be noted that, for convenience of explanation, the parts which will become the respective components of the interconnect substrate 100 in the end are described with the reference numerals indicative of the final components.

Each foil 95 has a first portion 96 and second portions 97. The first portion 96 is a portion to be removed when the cavity 81 is formed, and the second portions 97 are portions to become the pads 98. After preparation of the support substrate 90, the foils 95 are processed so as to leave the first portion 96 and the second portions 97, as illustrated in FIG. 2B. For example, the foil 95 are processed by etching. The foils 95 are each an example of a first metal layer.

As illustrated in FIG. 2C, the insulating layer 10 is disposed on the insulating layer 94, the first portion 96, and the second portions 97 on each side of the substrate 91, followed by placing a foil 51 on the insulating layer 10. The insulating layer 10 covers the foil 95. The insulating layer 10 and the foil 51 may be formed by applying heat and pressure simultaneously. The insulating layer 10 may be formed by attaching an uncured resin film and then applying heat. The insulating layer 10 may alternatively be formed by applying a liquid resin.

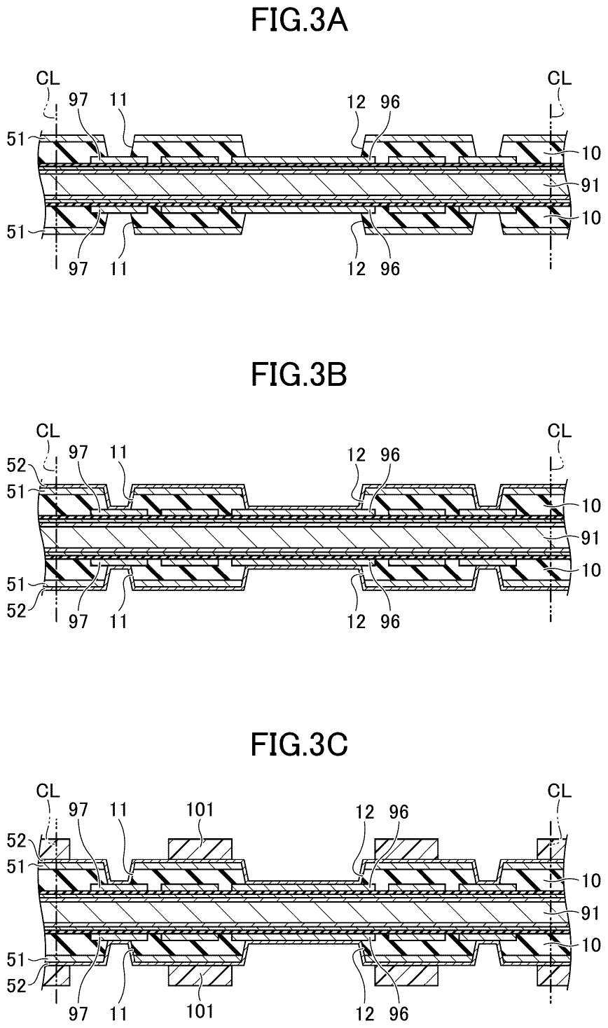

Subsequently, as illustrated in FIG. 3A, the foil 51 and the insulating layer 10 are processed by a laser to form openings in the foil 51 and the via holes 11 and 12 in the insulating layer 10. The via hole 12 reaches the first portion 96, and the via holes 11 reach the respective second portions 97. In plan view, the via hole 12 is formed in a rectangular shape, for example, and each of the via holes 11 is formed in a circular shape, for example. The via hole 12 is an example of a first opening.

As illustrated in FIG. 3B, the seed layer 52 is disposed on the upper surface of the first portion 96, the upper surfaces of the second portions 97, the inner wall surface of the via hole 12, the inner wall surfaces of the via holes 11, the inner wall surfaces of the openings formed in the foil 51, and the upper surface of the foil 51 on each side of the substrate 91. The seed layer 52 may be formed by, for example, electroless plating.

As illustrated in FIG. 3C, a plating resist layer 101 having openings is formed on the seed layer 52 on each side of the substrate 91. The openings of the plating resist layer 101 are formed in the portions where the interconnect layer 50 is to be formed.

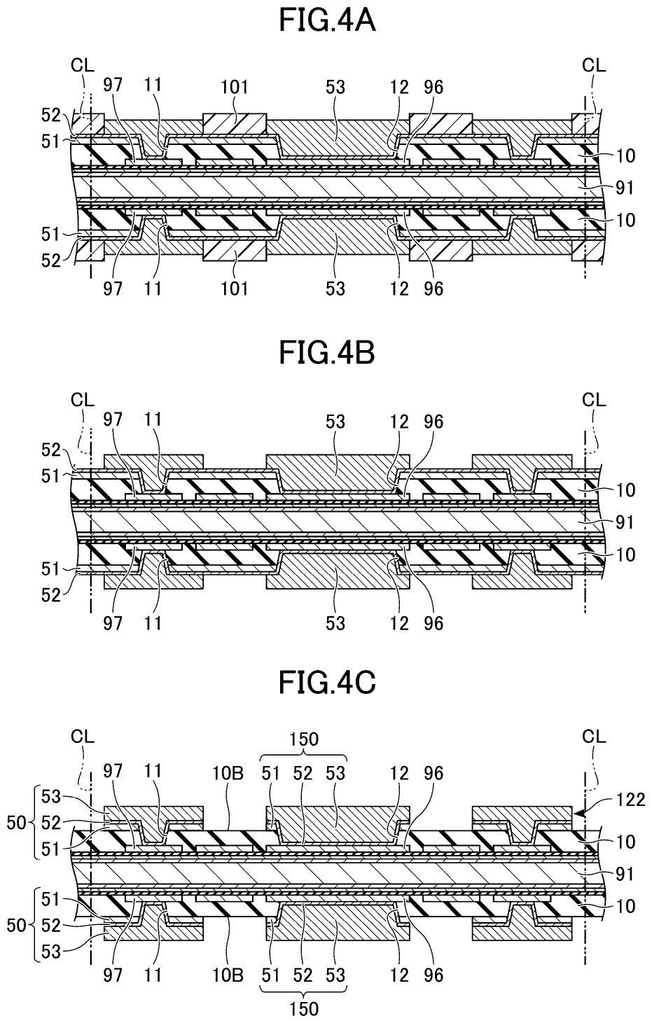

As illustrated in FIG. 4A, the plating layer 53 is formed in the openings of the plating resist layer 101 on each side of the substrate 91 by an electrolytic plating method using the seed layer 52 as the power supply path for plating.

Thereafter, as illustrated in FIG. 4B, the plating resist layer 101 is removed.

As illustrated in FIG. 4C, on each side of the substrate 91, the portions of the seed layer 52 exposed outside the plating layer 53 are removed, and the portions of the foil 51 exposed outside the plating layer 53 are also removed. In the removal of the seed layer 52 and the foil 51, for example, flash etching is performed. This arrangement effectively enables the formation of a metal layer 122, which includes both the interconnect layer 50 electrically connected to the second portions 97 and a third portion 150 in contact with the first portion 96. The interconnect layer 50 and the third portion 150 each include the foil 51, the seed layer 52, and the plating layer 53. The interconnect layer 50 is formed in the via hole 11 and on the surface 10B of the insulating layer 10. The third portion 150 is formed in the via holes 12 and on the surface 10B of the insulating layer 10. The metal layer 122 is an example of a second metal layer.

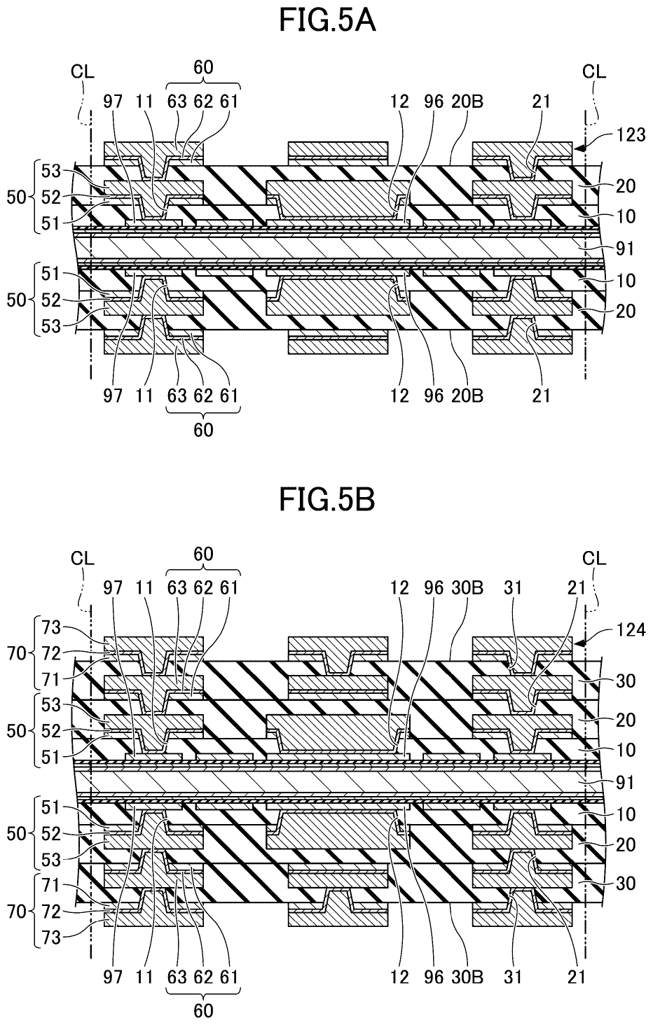

Subsequently, as illustrated in FIG. 5A, the insulating layer 20, the via holes 21, the foil 61, the seed layer 62, and the plating layer 63 are formed on each side of the substrate 91 in substantially the same manner as the insulating layer 10, the via holes 11, the foil 51, the seed layer 52, and the plating layer 53. The insulating layer 20 covers the metal layer 122. This arrangement allows the effective formation of a metal layer 123 having the interconnect layer 60 electrically connected to the interconnect layer 50. The interconnect layer 60 includes the foil 61, the seed layer 62, and the plating layer 63. The interconnect layer 60 is formed in the via holes 21 and on the surface 20B of the insulating layer 20. The metal layer 123 is an example of a third metal layer.

As illustrated in FIG. 5B, the insulating layer 30, the via holes 31, the foil 71, the seed layer 72, and the plating layer 73 are formed on each side of the substrate 91 in substantially the same manner as the insulating layer 10, the via holes 11, the foil 51, the seed layer 52, and the plating layer 53. The insulating layer 30 covers the metal layer 123. This arrangement enables the effective formation of a metal layer 124 having the interconnect layer 70 electrically connected to the interconnect layer 60. The interconnect layer 70 includes the foil 71, the seed layer 72, and the plating layer 73. The interconnect layer 70 is formed in the via holes 31 and on the surface 30B of the insulating layer 30. The metal layer 124 is an example of the fourth metal layer.

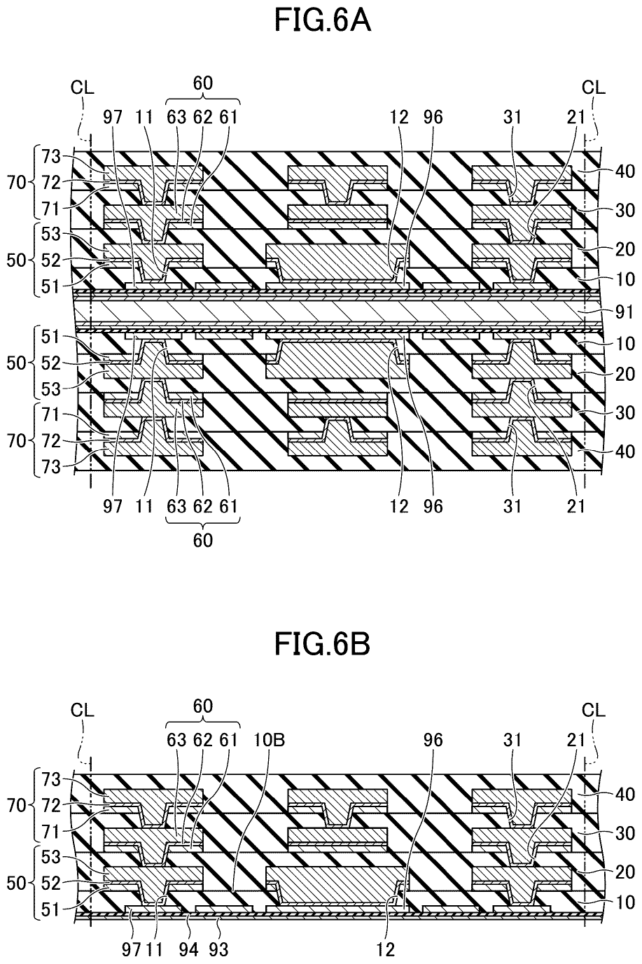

As illustrated in FIG. 6A, the insulating layer 40 is disposed on the metal layer 124 on each side of the substrate 91 in substantially the same manner as the insulating layer 10. The insulating layer 40 covers the metal layer 124.

Subsequently, as illustrated in FIG. 6B, the foil 93 and the carrier foil 92 are separated from each other, thereby detaching the carrier foil 92 and the substrate 91.

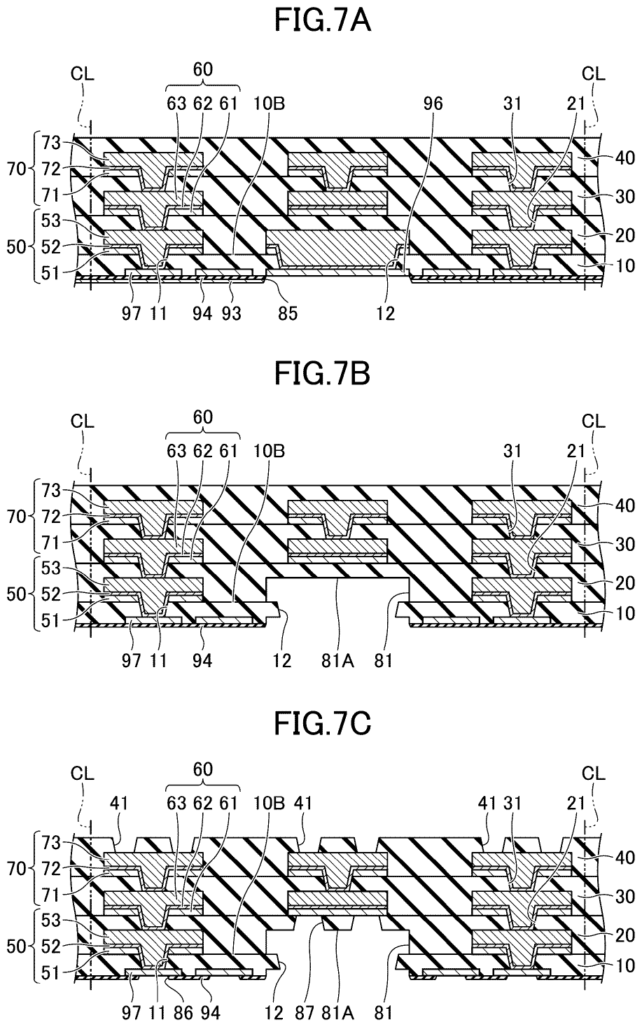

As illustrated in FIG. 7A, the foil 93 and the insulating layer 94 are processed by a laser to form an opening 85 in the foil 93 and the insulating layer 94. The opening 85 reaches the first portion 96. In plan view, the opening 85 is formed in a rectangular shape, for example. The opening 85 is an example of a second opening.

As illustrated in FIG. 7B, the first portion 96 and the third portion 150 are removed through the opening 85. At this time, the foil 93 is also removed. The foil 93, the first portion 96, and the third portion 150 may be removed, for example, by wet etching. Removing the first portion 96 and the third portion 150 results in the formation of the cavity 81 including the opening 85. The cavity 81 penetrates the insulating layers 94 and 10, and has the end surface 81A in the insulating layer 20.

As illustrated in FIG. 7C, the insulating layer 94 is processed by a laser to form the openings 86 in the insulating layer 94. The openings 86 reach the respective second portions 97. Further, the openings 41 are formed in the insulating layer 40 by processing the insulating layer 40 with a laser. The openings 41 reach the interconnect layer 70. Moreover, the openings 87 reaching the interconnect layer 60 are formed in the insulating layer 20 by processing the insulating layer 20 with a laser at the end surface 81A of the cavity 81. The openings 86 are each an example of a third opening.

Subsequently, the structure illustrated in FIG. 7C is cut by a slicer or the like along the cutting lines CL. The structure is thus singulated into the interconnect substrates 100, providing a plurality of interconnect substrates 100 according to the embodiment. By following these steps, the successful manufacture of the interconnect substrate 100 according to the embodiment is achieved.

### [Advantageous Effects of Interconnect Substrate]

In the interconnect substrate 100, the cavity 81 is formed by removing the first portion 96 of the foil 95 and the third portion 150 of the metal layer 122. The depth of the cavity 81 depends on the thickness of the insulating layer 94, the insulating layer 10, the foil 51, the seed layer 52, and the plating layer 53. Therefore, the stable formation of the cavity 81 having a sufficient depth is enabled by adjusting the thickness of the insulating layer 94, the insulating layer 10, the foil 51, the seed layer 52, and the plating layer 53.

When the first portion 96 of the foil 95 and the third portion 150 of the metal layer 122 are removed, the second portions 97 of the foil 95, which are to become the pads 98, are covered with the insulating layer 94. Because of this, the etching solution does not come in contact with the second portions 97, which serves to prevent the etching of the second portions 97. Moreover, the infiltration of the etching solution into the interface between the second portions 97 and the insulating layer 10 is effectively suppressed.

Furthermore, since the pads 98 are formed of the foil 95, the flatness of the surface of the pads 98 on the insulating layer 94 side is high.

### [Example of Usage of Interconnect Substrate]

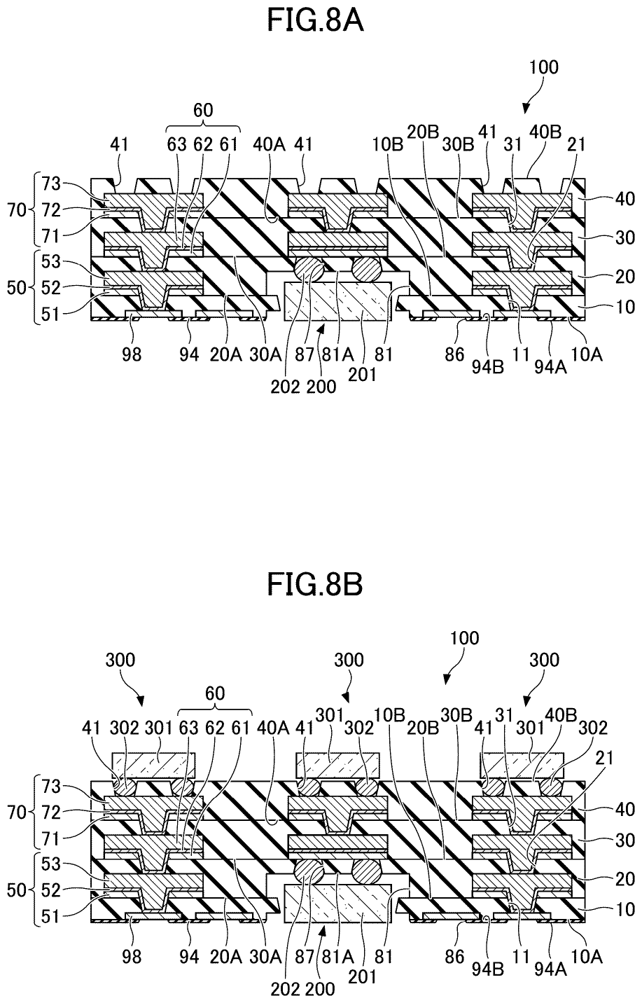

In the following, examples of usage of the interconnect substrate 100 will be described. FIGS. 8A and 8B are views illustrating examples of the usages of the interconnect substrate according to the embodiment.

In the first usage illustrated in FIG. 8A, a semiconductor device 200, which is an example of an electronic component and includes a core part 201 and terminals 202, is mounted on the interconnect substrate 100 so as to fit in the cavity 81. The terminals 202 are connected to the interconnect layer 60. The cavity 81 may be filled with an encapsulating resin (not shown) to encapsulate the semiconductor device 200.

In the second usage illustrated in FIG. 8B, the semiconductor device 200 is mounted on the interconnect substrate 100 so as to fit in the cavity 81 as in the first usage. Furthermore, capacitors 300, each of which is an example of an electronic component and includes a core part 301 and terminals 302, are mounted on the insulating layer 40. The terminals 302 are connected to the interconnect layer 70. Alternatively, one or more capacitors 300 may be mounted in the cavity 81 and the semiconductor device 200 may be mounted on the insulating layer 40. In this case, an encapsulating resin (not shown) may fill the cavity 81 to encapsulate the one or more capacitors 300.

### [Variation of Embodiment]

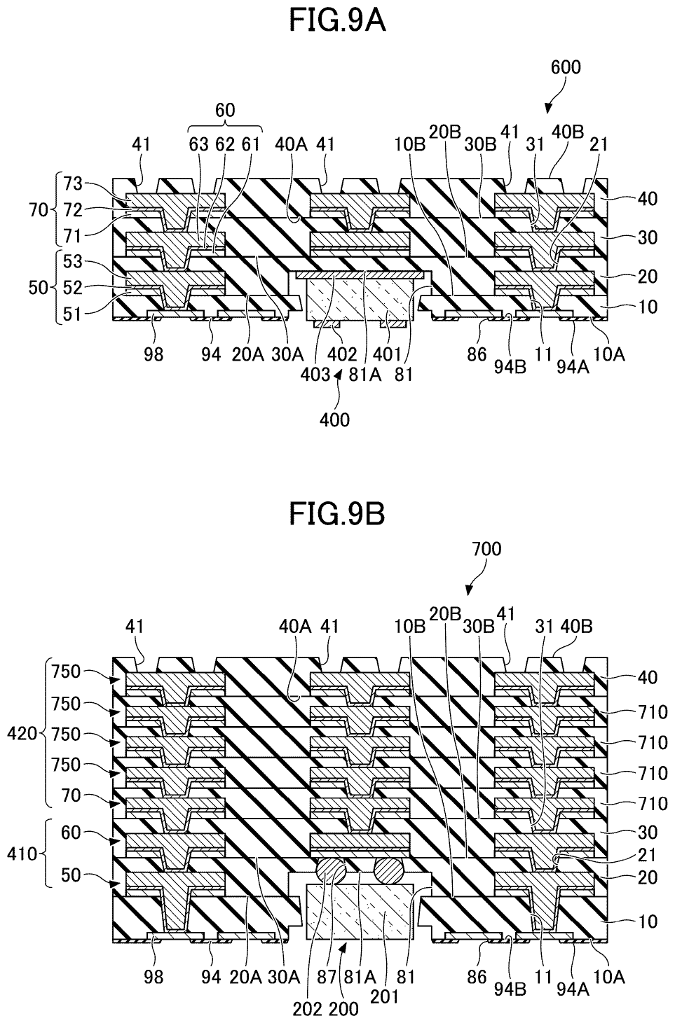

In the following, variations of the embodiment will be described. FIGS. 9A and 9B are cross-sectional views illustrating examples of interconnect substrates according to variations of the embodiment and examples of usages of the interconnect substrate.

As illustrated in FIG. 9A, an interconnect substrate 600 according to a first variation is structured such that no openings 87 are formed in the end surface 81A of the cavity 81. Other configurations of the interconnect substrate 600 are the same as those of the interconnect substrate 100.

A semiconductor device 400, which is an example of an electronic component and includes a core part 401 and terminals is mounted on the interconnect substrate 600 so as to be accommodated in the cavity 81, with the terminals 402 facing downward. An adhesive 403 such as an electrically conductive adhesive is disposed on the end surface 81A, and the semiconductor device 400 is bonded to the end surface 81A via the adhesive 403. The terminals 402 of the semiconductor device 400 may be connected to the pads 98 by bonding wires (not shown). The cavity 81 may also be filled with an encapsulating resin (not shown) to encapsulate the semiconductor device 400.

As illustrated in FIG. 9B, an interconnect substrate 700 according to the second variation has a plurality of insulating layers 710 between the insulating layers 30 and 40. The interconnect substrate 700 includes interconnect layers 750 between adjacent insulating layers 30 and 710, between two adjacent insulating layers 710, and between adjacent insulating layers 710 and 40. Via holes are formed in the insulating layers 710, and each interconnect layer 750 is electrically connected to the interconnect layer 750 or 70 situated one layer below. The insulating layers 10 and 20 are thicker than the insulating layers 710. In the second variation, the insulating layers 30, 40 and 710 are each an example of a fourth insulating layer, and the interconnect layers 70 and 750 are each an example of a third interconnect layer.

The interconnect substrate 700 has an antenna circuit 410 including at least a part of the interconnect layers 50 and 60, and a radio frequency (RF) module circuit 420 including at least a part of the interconnect layers 70 and 750.

The other configurations of the interconnect substrate 700 are the same as those of the interconnect substrate 100.

In the second variation, the antenna circuit 410 includes at least a part of the interconnect layers 50 and 60, and the radio frequency module circuit 420 includes at least a part of the interconnect layers 70 and 750. Moreover, the insulating layers 10 and 20 are thicker than the insulating layers 710. With this arrangement, desirable characteristics can be obtained for both the antenna circuit 410 and the radio frequency module circuit 420.

In this disclosure, it is not necessary for the second insulating layer to consist of a single insulating layer, but the second insulating layer may consist of a plurality of laminated insulating layers. This arrangement readily enables the formation of a deeper cavity. When the second insulating layer consists of a plurality of insulating layers, an interconnect layer may be provided between adjacent second insulating layers.

According to at least one embodiment, an interconnect substrate allows the stable formation of a deep cavity.

The present disclosures non-exhaustively include the subject matter set out in the following clauses.

Clause 1. A method of making an interconnect substrate, comprising:
forming a first metal layer including a first portion and a second portion on a first surface of a first insulating layer;
removing the first metal layer except for the first portion and the second portion on the first surface;
forming, on the first surface, a second insulating layer covering the first portion and the second portion, the second insulating layer having a second surface facing the first surface and a third surface opposite the second surface;
forming, in the second insulating layer, a first opening reaching the first portion;
forming a second metal layer in the first opening and on the third surface, the second metal layer having a third portion in contact with the first portion;
forming, on the third surface, a third insulating layer covering the second metal layer;
forming, in the first insulating layer, a second opening reaching the first portion;
removing the first portion and the third portion through the second opening; and
forming, in the first insulating layer, a third opening reaching the second portion.

Clause 2. The method as recited in clause 1, wherein the third insulating layer has a fourth surface facing the third surface and a fifth surface opposite the fourth surface, and the method further comprises:
forming a third metal layer on the fifth surface;
laminating, onto the fifth surface, a plurality of fourth insulating layers covering the third metal layer;
forming a fourth metal layer between adjacent ones of the fourth insulating layers.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. An interconnect substrate comprising:
a first insulating layer having a first surface;
a pad disposed on the first surface;
a second insulating layer disposed on the first surface and covering the pad, the second insulating layer having a second surface facing the first surface and a third surface opposite the second surface;
a first interconnect layer disposed on the third surface; and
a third insulating layer disposed on the third surface and covering the first interconnect layer,
wherein a recess penetrates the first insulating layer and the second insulating layer and has an end surface in the third insulating layer, and
wherein an opening is formed in the first insulating layer, and the pad is exposed through the opening.

2. The interconnect substrate as claimed in claim 1, further comprising a second interconnect layer, a third interconnect layer, and a plurality of fourth insulating layers,
wherein the third insulating layer has a fourth surface facing the third surface and a fifth surface opposite the fourth surface,
wherein the second interconnect layer is disposed on the fifth surface, and
wherein the plurality of fourth insulating layers are laminated on the fifth surface and cover the second interconnect layer, and the third interconnect layer is provided between adjacent ones of the fourth insulating layers.

3. The interconnect substrate as claimed in claim 2, comprising:
an antenna circuit including at least a part of the first interconnect layer; and
a high frequency module circuit including at least a part of the third interconnect layer.

4. The interconnect substrate as claimed in claim 3, wherein the second insulating layer is thicker than the fourth insulating layers sandwiching the third interconnect layer that is included in the high frequency module circuit.
